(19) United States
(12) Patent Application Publication
(10) Pub. No.: US 2009/0070992 A1
(43) Pub. Date: Mar. 19, 2009

(54) Pick And Place System For A Semiconductor Mounting Apparatus

(75) Inventor: Florentin Etter, Greifensee (CH)

Correspondence Address: Nixon Peabody LLP, 200 Page Mill Road, Palo Alto, CA, 94306, US

(73) Assignee: Oerlikon Assembly Equipment AG, Steinhausen, Cham (CH)

(21) Appl. No.: 12/206,644

(22) Filed: Sep. 8, 2008

(30) Foreign Application Priority Data
Sep. 18, 2007 (CH) 1560/07
Jan. 29, 2008 (CH) 145/08

(51) Int. Cl. H05K 13/04; H05K 3/30

(52) U.S. Cl. 29/741; 29/740

(57) ABSTRACT

A semiconductor mounting apparatus contains a pick and place system having a bonding head, which has a first drive system and a second drive system for displacing the bonding head in a predetermined direction. The first drive system has a first pivot arm and a first stationary situated drive, which is used to pivot the pivot arm back-and-forth within a predefined pivot range. The second drive system is mounted on the pivot arm and comprises a stationary situated electric motor.

### PRIORITY CLAIM

Applicant hereby claims foreign priority under 35 U.S.C § 119 from Swiss Application No. 1560/07 filed Sep. 18, 2007 and Swiss Application No. 145/08 filed Jan. 29, 2008, the disclosures of which are herein incorporated by reference.

### FIELD OF THE INVENTION

The invention relates to a pick and place system for a semiconductor mounting apparatus.

### BACKGROUND OF THE INVENTION

Various types of mounting apparatuses are known for mounting semiconductor chips on a substrate, which mount semiconductor chips on a substrate with high speed and great precision. Such mounting apparatuses are known as die bonders and are known, for example, from U.S. Pat. Nos. 6,185,815, 7,146,718 and 7120995 and European patent application EP 991110. The semiconductor chips are provided on a wafer table. The substrates to be equipped are supplied cyclically in sequence, one substrate at a time being fixed on a substrate table and being provided for equipping with semiconductor chips. The mounting of the semiconductor chips is performed using a bonding head driven by a pick and place system, on which a chip gripper is attached.

In the die bonder, the substrates are advanced cyclically by a transport unit and, for substrates having multiple substrate places lying in columns adjacent to one another, processed in columns. The substrate is always advanced when one column is completely equipped with semiconductor chips. The pick and place system known from U.S. Pat. No. 6,185,815 contains a lever mechanism having two pivot levers, which are moved back and forth between two terminal positions using alternating pivot directions. The two pivot levers are located in a stretched position to one another in the two terminal positions. The chip gripper receives a semiconductor chip from the wafer table when the two pivot levers are located in the first terminal position, and puts the semiconductor chip down on the substrate when the two pivot levers are located in the second terminal position. Very high placement precision is achieved using this lever mechanism. However, the disadvantage is that the semiconductor chip may only be put down at one single point on the substrate. The pick and place system known from EP 1480507 comprises a carriage movable along a linear y axis, on which a pivot arm is fastened. The bonding head with the chip gripper is fastened to the pivot arm. The semiconductor chip may be put down on the substrate at any arbitrary point of the y axis. However, the disadvantage is that the carriage must carry along the entire weight of the pivot arm and the drive for the pivot arm, i.e., a large mass.

The pick and place systems known from European patent application EP 991110 and U.S. Pat. No. 7,120,995 comprise a carriage movable along a linear y axis. With these solutions, high speeds and high precision are difficult to achieve, because the carriage must cover a relatively large distance.

### SUMMARY OF THE INVENTION

The invention is based on the object of developing a pick and place system which does not have the cited disadvantages.

### BRIEF DESCRIPTION OF THE DRAWING FIGURES

The accompanying drawings, which are incorporated into and constitute a part of this specification, illustrate one or more embodiments of the present invention and, together with the detailed description, serve to explain the principles and implementations of the invention. The figures are not to scale. In the drawings:

FIGS. 1 and 2 show a die bonder in lateral and schematic views,

FIG. 3 shows a pick and place system of the die bonder in a perspective view,

FIG. 4 shows a drive mechanism with two pivot levers,

FIG. 5 shows a mechanism to maintain the orientation of a shaft mounted on a pivot arm, and

FIG. 6 shows a decoupling mechanism.

### DETAILED DESCRIPTION OF THE INVENTION

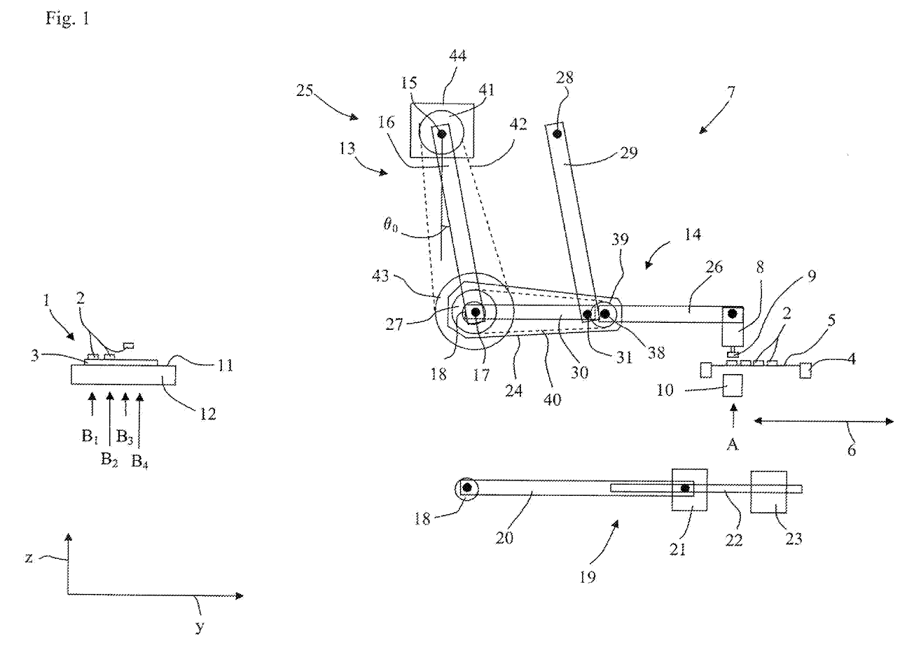

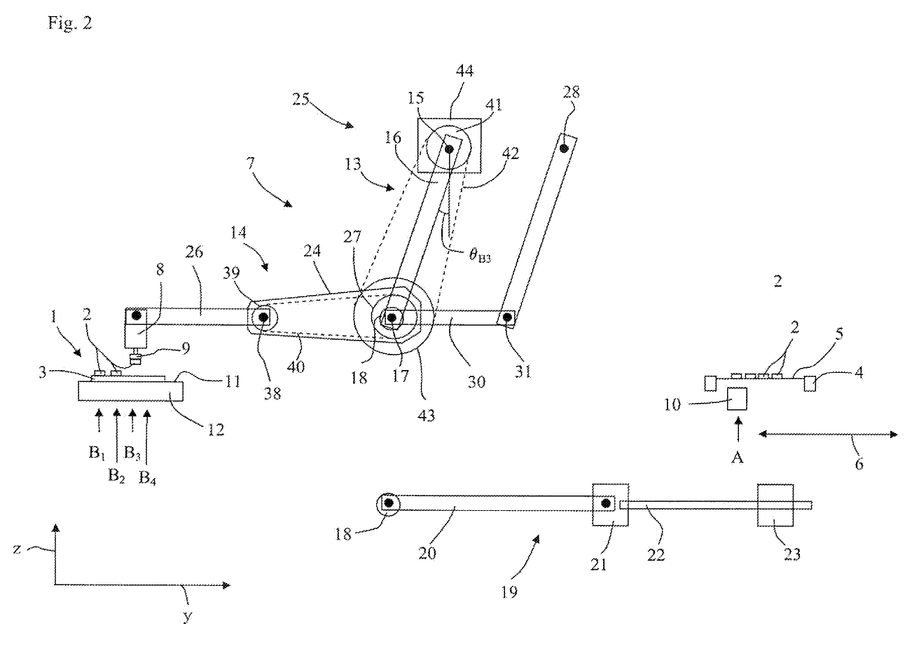

FIGS. 1 and 2 show a lateral and schematic view of a die bonder insofar as it is required for understanding the invention. The die bonder comprises a dispensing station (not shown), where adhesive or solder is applied to the substrate, and a bonding station 1, where the semiconductor chips 2 are placed on the substrate 3. The substrates 3 are transported cyclically by a transport unit (not shown) in a predetermined transport direction to the dispensing station and to the bonding station 1. The transport direction runs perpendicularly to the plane of the drawing of FIG. 1. The semiconductor chips 2 are provided on a wafer table 4, which receives a wafer sawn into the individual semiconductor chips 2. The semiconductor chips 2 are situated adjacent to one another in rows and columns and adhere to a carrier tape 5 expanded in a frame. The wafer table 4 is movable in two orthogonal directions, the wafer table 4 in operation providing the particular next semiconductor chip to be placed at a fixed location A. One movement direction of the wafer table 4 is shown by an arrow 6, the other movement direction of the wafer table 4 runs perpendicular to the plane of the drawing. A pick and place system 7 having a bonding head 8 and a chip gripper 9 mounted on the bonding head 8 is used to take the semiconductor chip 2 provided by the wafer table 4 at the location A and place it at a predefined location B₁ or B₂ or . . . Bₙ on the substrate 3, the index n identifying the number of the substrate places, which are situated adjacent to one another on the substrate 3 viewed in the transport direction of the substrates. In the example, n=4. The wafer table 4 comprises a chip ejector 10, a so-called die ejector, which supports the removal of the semiconductor chips 2 from the carrier tape 5.

In the bonding station 1, the substrate 3 lies on a horizontally oriented support surface 11 of a substrate table 12. The pick and place system 7 comprises two drive systems 13 and 14, to take the semiconductor chip 2 from the wafer table 4 at the location A, transport it in the y direction, and place it at one of the predefined locations B₁ or B₂ or . . . Bₙ on the substrate 3. Both drive systems 13 and 14 act in the y direction. The first drive system 13 is a rotational drive system, which is used to move the second drive system 14 in the y direction by a distance settable arbitrarily within predefined limits. The second drive system 14 is preferably the lever mechanism having two pivot levers known from EP 923111. The second drive system 14 may also be the lever mechanism also having two pivot levers known from EP 877544 or a lever mechanism having a single pivot lever. The second drive system 14 moves the chip gripper 9 in the y direction by a fixed predetermined distance.

The first drive system 13 comprises a pivot arm 16 rotatable around a first stationary axis 15, a first shaft 18 mounted on the pivot arm 16 on a second axis 17 running parallel to the first stationary axis 15, and a first, stationary situated drive 19, which is used to move the pivot arm 16 back and forth within a predefined pivot range θ₁ and θ₂. An arbitrary suitable drive may be used for this task. For reasons of illustrative clarity, the first drive 19 is shown offset downward in FIG. 1. In the present exemplary embodiment, the first drive 19 comprises a connecting rod 20, a nut 21, a spindle 22, and an electric motor 23. The connecting rod 20 is mounted at one end on the first shaft 18 so it is rotatable and at its other end on the nut 21 so it is rotatable. The spindle 22 engages in the nut 21 and is driven by the electric motor 23. When the electric motor 23 rotates, the spindle 22 moves the nut 21 along the longitudinal axis of the spindle 22. It is important that the connecting rod 20 is mounted without play on the first shaft 18 and on the nut 21.

The second drive system 14 comprises at least one pivot lever 24 mounted on the first shaft 18 and a second drive 25 for the rotation of the first pivot lever 24 around the first shaft 18. In the present example, the second drive system 14 also comprises a second pivot lever 26. The chip gripper 9 is mounted either directly on the second pivot lever 26 or, as in the present example, on an element operationally linked to the second pivot lever 26.

The pick and place system 7 further comprises a second shaft 27, which is mounted on the first shaft 18, and a mechanism which ensures that the second shaft 27 maintains its orientation unchanged upon a rotation of the pivot arm 16. Three examples of such a mechanism are explained hereafter.

In the first example shown in FIGS. 1 and 2, the mechanism is formed by the pivot arm 16, an arm 29 rotatable around a third stationary axis 28, and a connection arm 30. The connection arm 30 is mounted on the first shaft 18 so it is rotatable around the second axis 17 and is mounted on the arm 29 so it is rotatable around a fourth axis 31. The length of the arm 29, measured from the third axis 28 to the fourth axis 31, is equal to the length of the pivot arm 16, measured from the first axis 15 to the second axis 17. The length of the connection arm 30, measured from the second axis 17 to the fourth axis 31, is equal to the distance between the first axis 15 and the third axis 28. The first axis 15, the second axis 17, the third axis 28, and the fourth axis 31 run parallel to one another and form a changeable parallelogram, in which the connection arm 30 is always oriented identically. The second shaft 27 is seated on the first shaft 18 of the first drive system 13 and is connected fixed to the connection arm 30. The second shaft 27 therefore cannot rotate, its rotational position is always the same.

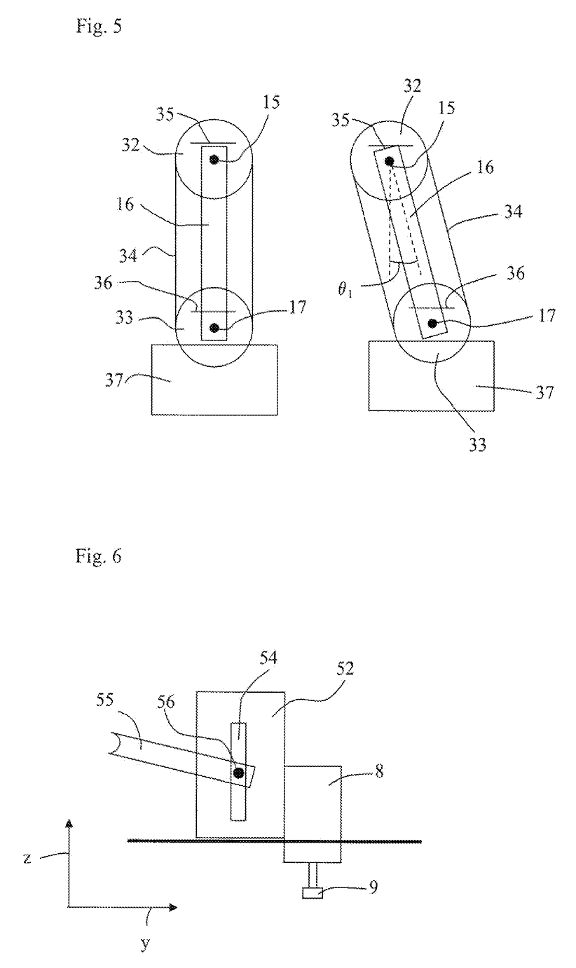

In the second example shown in FIG. 5, the mechanism is formed by the pivot arm 16, a first toothed belt disc 32, which is mounted on the first stationary axis 15, a second toothed belt disc 33, which is mounted at a distance to the first axis 15 at an arbitrary point on the pivot arm 16 so it is rotatable around a second axis 17, and a toothed belt 34, which wraps around the two toothed belt discs 32 and 33. The diameter of the two toothed belt discs 32 and 33 is equal. The first toothed belt disc 32 is situated fixed in place, i.e., it cannot rotate around the first axis 15. The state is shown on the left in FIG. 5 when the pivot arm 16 encloses the angle θ=0° with the vertical, the state is shown on the right in FIG. 5 when the pivot arm 16 encloses the angle θ=θ₁° with the vertical. A first line 35 illustrates the unchangeable rotational position of the first toothed belt disc 32, a second line 36 illustrates the rotational position of the second toothed belt disc 33, which is also unchangeable. When the first drive 19 (FIG. 1) rotates the pivot arm 16, the toothed belt 34 rolls on the second toothed belt disc 33. Because the diameter of the two toothed belt discs 32 and 33 is equal, the second toothed belt disc 33 does not rotate. A component 37 may be fastened to the second toothed belt disc 33 as shown, which always maintains its orientation in space because of this mechanism. The first pivot lever 24 is preferably mounted on the pivot arm 16, for example on the second axis 17, but it may also be mounted on the component 37.

The third mechanism is similar to the second mechanism with the difference that the two toothed belt discs 32 and 33 are each replaced by a gear wheel and the toothed belt by an intermediate gear wheel mounted in the middle between the two gear wheels on the pivot arm 16, the intermediate gear wheel meshing with the two gear wheels. The mechanism is similar to the mechanism described later on the basis of FIG. 4.

In the example shown in FIGS. 1 and 2, the second drive system 14 is based on the lever mechanism described in EP 923111, which comprises the first pivot lever 24 and the second pivot lever 26. The first pivot lever 24 is mounted so it is rotatable on the first shaft 18, i.e., the first pivot lever 24 is rotatable around the second axis 17. The second pivot lever 26 is mounted so it is rotatable on a pin 38 on the end of the first pivot lever 24 facing away from the first shaft 18. A toothed belt disc 39 connected fixed to the second pivot lever 26 is mounted on the pin 38. A toothed belt 40 wraps around the second shaft 27 and the toothed belt disc 39, the toothed belt 40 being fastened to the second shaft 27. The second shaft 27 preferably contains a tensioning device to tension the toothed belt 40. The second shaft 27 may also be a toothed belt disc, although this is not absolutely necessary, namely because the toothed belt 40 is connected fixed to the second shaft 27.

The second drive system 14 further comprises a second drive 25, which is used to move the two pivot levers 24 and 26 back and forth between a first terminal position, in which they are in a stretched position to one another, and a second terminal position, in which they are in a stretched position to one another. Stretched position means that the two pivot levers 24 and 26 lie on a straight line. The second drive 25 comprises a toothed belt disc 41 mounted on the first axis 15, a toothed belt 42, and a third shaft 43 fastened rigidly to the first pivot lever 24. The toothed belt 42 wraps around the toothed belt disc 41 and the third shaft 43. The toothed belt 42 may also be fastened using a tensioning device to the third shaft 43. In the present exemplary embodiment, the first pivot lever 24 and the third shaft 43 are implemented as part of a housing which receives the second shaft 27, the toothed belt 40, and the toothed belt disc 39. A stationary situated motor 44, preferably an electric motor, drives the toothed belt disc 41 either directly or via a reduction gear. The toothed belt disc 39, the toothed belt 40, and the third shaft 43 form a transmission stage, whose ratio is in the example approximately 1:4, but may also be greater or less or also 1:1. The chip gripper 9 or the bonding head 8 having the chip gripper 9 is mounted on the exterior end of the second pivot lever 26 or, as shown in FIG. 6, on an element operationally linked to the exterior end of the second pivot lever 26.

FIG. 1 shows the pick and place system 7 in the pick position, in which the pivot arm 16 encloses the angle θ₁ with the vertical and the two pivot levers 24 and 26 are in the first terminal position, in which the bonding head 8 is at the location A above the semiconductor chip 2 to be received. The second pivot lever 26 is in this stretched position on the right side of the first pivot lever 24.

FIG. 2 shows the pick and place system 7 in a bonding position, in which the pivot arm 16 encloses the angle θ_{B3} with the vertical and the two pivot levers 24 and 26 are in the second terminal position, in which the bonding head 8 is at the location B₃ above the substrate place to be equipped. The second pivot lever 26 is in this stretched position on the left side of the first pivot lever 24.

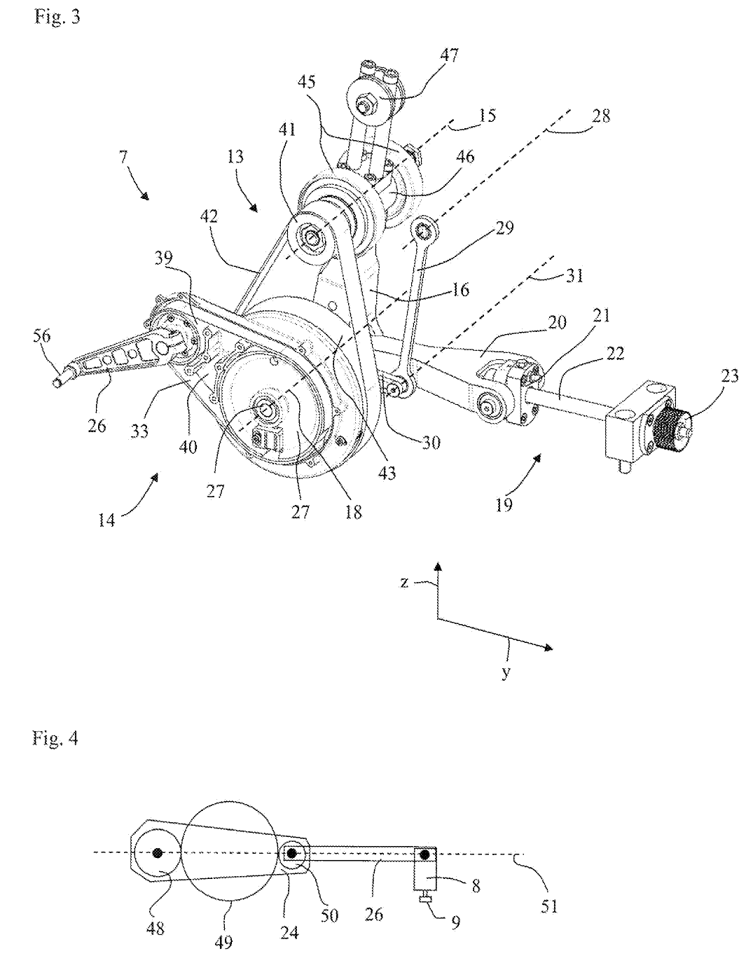

FIG. 3 shows a perspective view of the pick and place system 7 according to the invention for better illustration. Two stationary bearings 45 are shown, in which a hollow shaft 46 is mounted, which runs along the first axis 15. The pivot arm 16 is fastened on the hollow shaft 46. A shaft is mounted in the interior of the hollow shaft 46, which is driven by the electric motor 23 (FIG. 1) and on which the toothed belt disc 41 is seated. An equalization mass 47 is also fastened on the pivot arm 16, so that the pivot arm 16 is balanced.

FIG. 4 shows an embodiment in which the second shaft 27 is a first gear wheel 48 and in which an intermediate gear wheel 49 is provided instead of the toothed belt 40 and a second gear wheel 50 is provided instead of the toothed belt disc 39. The first gear wheel 48 is also connected fixed to the connection arm 30 (FIG. 1). The intermediate gear wheel 49 is mounted on the middle of the first pivot lever 24 so it is rotatable and meshes with the first gear wheel 48 and the second gear wheel 50. The two pivot levers 24 and 26 are located in a stretched position to one another in this illustration, i.e., they lie on a straight line 51.

The pick and place system 7 according to the invention allows the mounting of the semiconductor chips with great speed and high precision. The numeric values specified hereafter relate to the present exemplary embodiment. These numeric values are therefore only to be viewed as exemplary specifications, which may certainly vary. The pick and place system 7 transports the semiconductor chips 2 in the y direction by a distance D, which is between Dₘᵢₙ=260 and Dₘₐₓ=330 mm. The first drive system 13 moves the second drive system 14 by a settable path w, which lies between 0 and 70 mm, controlled by a program. The second drive system 14 covers an unchangeable distance Do between the two terminal positions, in which the first pivot lever 24 and the second pivot lever 26 are in a stretched position to one another. The distance D₀ is maintained with very great precision because of the exploitation of the stretched positions.

The distance D₀ is advantageously selected in such a way that D₀≈½(Dₘᵢₙ+Dₘₐₓ). In the present exemplary embodiment, D₀≈295 mm would then result. The y position of the first axis 15 is then correspondingly established in such a way that the bonding head 8 is above the pick position A when the pivot arm 16 of the first drive system 13 assumes the angle θ₀=½(θ₁+θ₂). When changing from the pick position to one of the cited bonding positions B₁ through B₄, the first drive system 13 must therefore cover at most the angle ½|θ₁−θ₂|, which corresponds in the present case to the maximum path of 35 mm. The first drive system 13 only covers a path which corresponds to approximately a tenth of the maximum path of the pick and place system 7 and lies in a technical range in which a high precision is also achievable at a speed sufficient for the application.

The second axis 17 is moved back and forth on a circular path. The first shaft 18 rotates around an angle corresponding to the rotation. In order that the first pivot lever 24 and the second pivot lever 26 are in the stretched position to one another both in the first terminal position, in which the bonding head 8 is in the pick position above the wafer table 4, and also in the second terminal position, in which the bonding head 8 is in an arbitrary mounting position above the substrate table 12, the first pivot lever 24, upon the change from one terminal position into the other terminal position, must always, independently of the current rotational angle θ of the pivot arm 16, rotate by an angle of 180° and the second pivot lever 26 most rotate by twice this angle of 360°. To achieve this, it is necessary on the one hand for the second shaft 27 to always maintain its orientation. The parallelogram formed by the pivot arm 16, the arm 29, and the connection arm 30 ensures this: the connection arm 30 never changes its direction. Therefore, the second shaft 27 also does not change its rotational position. On the other hand, it is necessary for the diameter of the second shaft 27 to be twice the diameter of the toothed belt disc 39.

When the second drive 25 rotates the third shaft 43 and the first pivot lever 24 connected fixed thereto around the first shaft 18, the toothed belt disc 39 rolls on the toothed belt 40, so that the second pivot lever 26 thus rotates twice as fast as the first pivot lever 24 and in the opposing rotational direction.

The pick and place system 7 according to the invention has the following advantages:
Greater throughput with high placement precision. The high placement precision of the lever mechanism having the two pivot levers 24 and 26 remains largely maintained, although arbitrary bonding positions within a predefined area may now be approached.
The electric motors 23 and 44 of the drives 19 and 25 are situated stationary, i.e., their mass does not have to be moved. The total mass to be moved is therefore much less than in the solutions of the prior art.
The supply of the electrical power is simple, a flexible power supply is not necessary.

The second drive system 14 may also comprise a lever mechanism different from that described above, which is based on U.S. Pat. No. 6,185,815, for example, the lever mechanism known from European patent application EP 877544, which also has two pivot levers. It is also possible to only use a single pivot lever, namely the first pivot lever 24 (FIG. 1), and to mount the bonding head 8 having the chip gripper 9 on the single pivot lever.

The two drive systems 13 and 14 of the pick and place system 7 have the task of moving the bonding head 8 at great speed in the y direction back and forth to the predefined positions B₁ through Bₙ (FIG. 1). The pick and place system 7 also has the task of raising and lowering the bonding head 8 and/or the chip gripper 9 in the z direction, and allowing facultative correction movements in the x direction, so that the semiconductor chip may be placed precisely in position on the corresponding substrate place. For this reason, it is advantageous to fasten the bonding head as schematically shown in FIG. 6 to a carriage 52, which is mounted so it is displaceable on a guide rail 53 running in the y direction. The carriage 52 contains a slot 54 running in the z direction, in which a pin 56 attached to the outermost pivot lever 55 of the second drive system 14 engages. (In the exemplary embodiment shown in FIG. 1, the second pivot lever 26 is the outermost pivot lever 55). This solution decouples every movement of the outermost pivot lever 55 in the z direction from the movement of the carriage 52 in the y direction and additionally allows the guide rail 53 to be raised and lowered in the z direction without feedback on the outermost pivot lever 55.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims and their equivalents.

What is claimed is:

1. A pick and place system for taking a semiconductor chip provided at a first location and subsequently placing it on a substrate, comprising
a chip gripper,
a first drive system having a pivot arm rotatable around a first stationary axis, a first shaft mounted on the pivot arm on a second axis running parallel to the first stationary axis and a first drive for rotating the pivot arm around the first stationary axis,
a second drive system, which comprises a first pivot lever mounted on the first shaft and a second drive for rotating the first pivot lever,
a second shaft, which is mounted on the first shaft, and
a mechanism which ensures that the second shaft maintains its orientation unchanged during a rotation of the pivot arm,
the second drive comprising a stationary situated motor, which is operationally linked to the first pivot lever via a transmission stage,
the chip gripper being mounted on an element operationally linked to the first pivot lever.

2. The pick and place system according to claim 1, wherein said mechanism is formed by the pivot arm, a further arm, and a connection arm, the further arm being mounted so it is rotatable around a third, stationary axis, the connection arm being mounted so it is rotatable around the second axis on the pivot arm and so it is rotatable around a fourth axis on the further arm, the first axis, the second axis, the third axis, and the fourth axis running parallel to one another and forming a changeable parallelogram.

3. The pick and place system according to claim 1, wherein said mechanism is formed by a first toothed belt disc, which is situated stationary on the first axis, and a second toothed belt disc, which is mounted on the pivot arm at a distance to the first toothed belt disc, the two toothed belt discs having equal diameter and being connected to one another via a toothed belt.

4. The pick and place system according to claim 1, wherein
the second drive system additionally comprises a second pivot lever, a toothed belt disc, and a toothed belt,
the second pivot lever is mounted so it is rotatable on a pin which is attached to the first pivot lever on the end of the first pivot lever facing away from the first shaft,
the toothed belt disc is mounted on the pin and is connected fixed to the second pivot lever,
the toothed belt ensures that upon a rotation of the first pivot lever by 180°, the second pivot lever rotates by 360°, and
the transmission stage comprises a further toothed belt disc mounted on the first axis, a third shaft, and a further toothed belt,
the third shaft is mounted on the first shaft and is connected fixed to the first pivot lever, and
the further toothed belt wraps around the further toothed belt disc and the third shaft.

5. The pick and place system according to claim 2, wherein
the second drive system additionally comprises a second pivot lever, a toothed belt disc, and a toothed belt,
the second pivot lever is mounted so it is rotatable on a pin which is attached to the first pivot lever on the end of the first pivot lever facing away from the first shaft,
the toothed belt disc is mounted on the pin and is connected fixed to the second pivot lever,
the toothed belt ensures that upon a rotation of the first pivot lever by 180°, the second pivot lever rotates by 360°,
the transmission stage comprises a further toothed belt disc mounted on the first axis, a third shaft, and a further toothed belt,
the third shaft is mounted on the first shaft and is connected fixed to the first pivot lever, and
the further toothed belt wraps around the further toothed belt disc and the third shaft.

6. The pick and place system according to claim 3, wherein
the second drive system additionally comprises a second pivot lever, a toothed belt disc, and a toothed belt,
the second pivot lever is mounted so it is rotatable on a pin which is attached to the first pivot lever on the end of the first pivot lever facing away from the first shaft,
the toothed belt disc is mounted on the pin and is connected fixed to the second pivot lever,
the toothed belt ensures that upon a rotation of the first pivot lever by 180°, the second pivot lever rotates by 360°, and
the transmission stage comprises a further toothed belt disc mounted on the first axis, a third shaft, and a further toothed belt,
the third shaft is mounted on the first shaft and is connected fixed to the first pivot lever, and
the further toothed belt wraps around the further toothed belt disc and the third shaft.

7. A semiconductor mounting apparatus having a pick and place system according to claim 1, in which the chip gripper is mounted on a bonding head, wherein the pivot arm is located approximately in a middle of its pivot range when the bonding head takes the semiconductor chip provided at the first location.

8. A semiconductor mounting apparatus having a pick and place system according to claim 2, in which the chip gripper is mounted on a bonding head, wherein the pivot arm is located approximately in a middle of its pivot range when the bonding head takes the semiconductor chip provided at the first location.

9. A semiconductor mounting apparatus having a pick and place system according to claim 3, in which the chip gripper is mounted on a bonding head, wherein the pivot arm is located approximately in a middle of its pivot range when the bonding head takes the semiconductor chip provided at the first location.

10. A semiconductor mounting apparatus having a pick and place system according to claim 4, in which the chip gripper is mounted on a bonding head, wherein the pivot arm is located approximately in a middle of its pivot range when the bonding head takes the semiconductor chip provided at the first location.

11. A semiconductor mounting apparatus having a pick and place system according to claim 5, in which the chip gripper is mounted on a bonding head, wherein the pivot arm is located approximately in a middle of its pivot range when the bonding head takes the semiconductor chip provided at the first location.

12. A semiconductor mounting apparatus having a pick and place system according to claim 6, in which the chip gripper is mounted on a bonding head, wherein the pivot arm is located approximately in a middle of its pivot range when the bonding head takes the semiconductor chip provided at the first location.
